(19) United States
(12) Patent Application Publication
(10) Pub. No.: US 2026/0147965 A1
(43) Pub. Date: May 28, 2026

(54) METHOD AND SYSTEM FOR DESIGN SPACE EXPLORATION, OPTIMIZATION, AND FINE-TUNING OF ANALOG CIRCUITS USING MACHINE LEARNING MODELS

(71) Applicant: ANALOG INTELLIGENT DESIGN INC., MORGAN HILL, CA (US)

(72) Inventors: ZIA ABBAS, Hyderabad (IN); Khanh Minh Le, Morgan hill, CA (US)

(21) Appl. No.: 19/401,891

(22) Filed: Nov. 26, 2025

Related U.S. Application Data
(60) Provisional application No. 63/724,965, filed on Nov. 26, 2024.

(51) Int. Cl. G06F 30/27; G06F 30/367

(52) U.S. Cl. CPC G06F 30/27; G06F 30/367

(57) ABSTRACT

The present invention discloses a method for performing design space exploration, design optimization, and fine-tuning of analog circuits using a machine learning (ML) model. The method includes designing a base analog circuit, collecting SPICE simulation data for a random number of combinations of input, output, and process, voltage and temperature conditions, generating the data set from the simulation results, training the ML model using the generated dataset, identifying dominant circuit components in the base analog circuit configuration using Pearson correlation coefficients, generating from the trained machine learning model, a group of candidate analog circuit designs based on boundary conditions and desired specifications, and from the group of candidates calculating the candidate circuit that meets all the optimization criteria and the boundary conditions. The method further includes fine-tuning the optimized circuit by re-optimizing it for one or more specific sets of input, output, or PVT conditions to bring its specifications to the desired values.

### BACKGROUND

### Technical Field

The embodiments herein generally relate to analog circuit design, and more particularly, to a method and a system for performing design space exploration, design optimization, and fine-tuning of analog circuits using machine learning (ML) models.

### Description of the Related Art

In the past 60 years, a method for analog circuit design has remained relatively unchanged. While new tools have been introduced, the Simulation Program with Integrated Circuit Emphasis (SPICE) and its derivatives remain the dominant tool for circuit simulation. However, SPICE simulations are highly resource-intensive, which demands substantial computational power and storage, with runtimes frequently extending to hours or even days. This generates a significant bottleneck in the analog circuit design, impacting overall efficiency.

SPICE simulations present such bottlenecks because SPICE is designed to solve complex equations that characterize intricate circuits and utilize advanced device models. Designers, who heavily depend on SPICE simulations, often spend weeks or months designing, analyzing, and optimizing the analog circuits to meet the required specifications across various process, voltage, and temperature (PVT) conditions. Multiple SPICE simulations are required to understand the relationships between the circuit components of the analog circuits and the PVT conditions. However, in most cases, the design process involves tedious manual iterations, which take significant time. Consequently, due to time and resource constraints, the designers may resort to “good enough” solutions rather than striving for fully optimized designs.

The existing analog circuit design method involves the steps of (a) defining specifications, (b) creating the preliminary circuit design, (c) running SPICE simulations and analyzing results, (d) redesigning and re-running simulations if specifications are not met, and (e) running further simulations to check best- and worst-case scenarios. The repetitive loop of steps (c), (d), and (e) occupies a significant portion of designers' time and computer resources, yet the existing analog circuit design process does not assure success. This process leads to delays in time-to-market, reduced competitiveness, increased cost, and lost revenue for analog design companies.

While SPICE simulations are essential for predicting circuit behaviour, the SPICE program demands substantial computational power, execution time, and storage. The analog circuit design-simulation-redesign loop continues to be the most prolonged aspect of the design workflow, which often requires weeks or months to complete. Furthermore, the lengthy simulation runtime and schedule pressure restrict the designers from thoroughly analyzing all input-output specification combinations, thereby increasing the risk of unexpected failure conditions. The above factors often lead to designers to an incomplete grasp of the interrelationships between the circuit components and the PVT conditions, and relies on simulations at perceived “troublesome” or “corner” cases to identify possible issues.

Modern simulators have significantly enhanced their performance through parallel processing, graphics processing unit (GPU) acceleration, and optimized algorithms. Despite these advancements, complex tasks such as Monte Carlo simulations still demand significant computation time. As technologies progress, the device models become increasingly intricate, which further prolongs SPICE simulations. For example, the SPICE models for MOS devices in 7 nanometres (nm) processes currently feature over 100 parameters, resulting in slower and more resource-intensive simulations than before.

As new technology nodes are launched and foundries provide their versions of similar generation process nodes, the demand for porting existing analog circuits to the new nodes has surged. The porting process follows the same steps as designing existing analog circuits, with the key difference being that it starts with an existing circuit from a different node. Consequently, process porting of existing analog circuits faces the same inefficiency challenges of traditional circuit design methodologies.

Due to the extensive time and resources required for SPICE-based analysis, the designers often turn to traditional knowledge from textbooks and personal experience, using SPICE simulations selectively to verify key assumptions. Consequently, due to time pressure and a desire to minimize risk, the designers tend to modify existing designs rather than explore new options.

This reliance on existing knowledge also limits thorough design space exploration (DSE), a systematic approach to evaluating different design alternatives before implementation. In DSE for the analog circuit design, different design options are assessed based on criteria such as power, performance, and cost. This process exposes trade-offs, thereby allowing designers to compare configurations based on their relative strengths and weaknesses to identify the most balanced solution for their objectives. The traditional design space exploration (DSE) method for analog circuit design is a systematic process in which a designer determines the circuit performance limits and verifies if the design meets all the specified requirements. This method involves defining the performance targets, creating an initial design, and testing how different component characteristics impact performance across various environmental conditions, called PVT conditions (process, voltage, temperature).

The process starts by varying key characteristics, such as the widths and lengths of MOS transistors, resistor and capacitor values, and PVT conditions, and then simulating the circuit with each variation to observe how these changes affect performance. For example, in an operational amplifier, the gain is sensitive to the sizes of MOS devices in the differential input stage. By adjusting the widths and gate lengths of these devices and running SPICE simulations, the designer may determine the range of sizes that attain the desired gain and the points where the amplifier falls out of specification or fails to operate.

The traditional DSE method has several problems leading to inefficiency. First, because it relies heavily on SPICE simulations, it is computationally intensive and slow. This limits the number of simulations that can be practically performed and restricts exploration breath and speed, which makes it difficult to use faster heuristic or statistical analyses. Additionally, each design change requires re-simulation across all relevant conditions, which leads to lengthy iteration cycles. Manual intervention is often needed to interpret results and make design adjustments, which creates bottlenecks in the workflow and makes it difficult to fully automate the DSE process.

The traditional design optimization method for analog circuits uses SPICE simulations to iteratively refine circuit components to attain desired specifications. Like DSE, the SPICE-based optimization process includes adjusting component characteristics, such as transistor dimensions, resistor and capacitor values, and environmental conditions (PVT), and then running simulations to verify the impact of these changes and adjusting the circuit component characteristics until the design is considered optimized, i.e. when specifications are met and nothing else can be done to improve them. The traditional SPICE-based optimization method depending entirely on SPICE simulations is slow and resource-intensive. This slows down the entire optimization process, which limits the number of design iterations that can be performed in a reasonable time frame. Each change in circuit parameters requires rerunning simulations, thereby creating lengthy change-simulation loops that significantly extend design time.

Moreover, the slow pace of SPICE simulations hinders the application of advanced optimization techniques, such as heuristic or statistical methods, which could yield more refined results. This constraint often leads to designs that may not be fully optimized. Additionally, the optimization process usually relies on human intervention to evaluate simulation results and make parameter adjustments, which is time-consuming and limits efficiency. The manual nature of this process also makes full automation challenging, restricting the potential for streamlining the optimization workflow. Recently, intermediate SPICE simulation results have been used to apply reinforced learning algorithms in analog circuit optimization, and more automation has been introduced to the workflow, but SPICE remains the major bottleneck.

Due to the complex interdependence between component characteristics, input and output conditions, PVT variations, and the analog circuit specifications, even optimized designs exhibit a spread in specification values across PVT conditions.

Accordingly, there remains a need to address the aforementioned technical problems for designing analog circuits.

### SUMMARY

In view of the foregoing, an embodiment herein provides a computer-implemented method for designing analog circuits using machine learning models. The method is executed by one or more processors of a computing system in communication with a machine-learning model and a circuit-simulation data database. The method includes (a) generating one or more analog circuit configurations using at least one design tool, (b) evaluating each of the one or more analog circuit configurations using at least one simulation tool to determine which analog circuit configurations meet predefined specifications under nominal conditions, (c) selecting a base analog circuit configuration from among the analog circuit configurations that meet the predefined specifications, (d) determining, through preliminary simulation, valid functional ranges for device sizes, device parameters, input conditions, output conditions, and Process, Voltage, and Temperature (PVT) conditions within which the base analog circuit configuration remains functional and all devices operate within operational limits, (e) generating, using at least one random sampling method, a plurality of randomly generated combinations of device sizes, device parameters, input conditions, output conditions, and PVT conditions selected from within the determined valid functional ranges, (f) performing SPICE simulations on the selected base analog circuit configuration for each of the plurality of randomly generated combinations to obtain simulation data comprising measured performance specification values, (g) normalizing and validating the simulation data using at least one data manipulation algorithm, (h) generating a training dataset from the normalized and validated simulation data, (i) training a machine learning model using the generated training dataset to generate a trained machine learning model, (j) performing at least one of design space exploration, design optimization, or fine-tuning of the analog circuit configuration using inference from the trained machine learning model executed on the one or more processors without reverting to SPICE simulation, and (k) generating a report for the analog circuit configuration based on results from step (j).

In some embodiments, the machine learning model is trained by: (a) selecting a machine learning model suitable for the type of analog circuit configuration being designed, (b) optimizing hyperparameters of the machine learning model to minimize errors between predicted values and actual values, and (c) assessing performance of the trained machine learning model by determining a performance metric indicating predictive accuracy.

In some embodiments, the step of performing design space exploration comprises: (a) identifying dominant circuit components by computing sensitivity measures or correlation metrics, (b) determining specification values using the trained machine learning model without SPICE simulation, (c) modifying device parameters, (d) iteratively repeating until convergence, and (e) generating a design space exploration report with graphical visualizations.

In some embodiments, the step of performing design optimization comprises: (a) receiving optimization criteria and boundary conditions, (b) generating candidate analog circuit designs, (c) determining boundary values using the trained machine learning model, (d) identifying an optimized design by numerically solving multi-variable dependency relationships, (e) validating boundary values, and (f) iteratively recomputing until convergence.

In some embodiments, the step of performing fine-tuning comprises: (a) receiving an optimized analog circuit design comprising device-level parameters previously determined to satisfy nominal specification values across predefined PVT ranges, (b) receiving, via a user interface, fine-tuning criteria comprising target PVT conditions, target specification values, and boundary conditions defining permitted ranges for one or more specification values, (c) computing, by executing the trained machine learning model on the one or more processors, sensitivity measures or correlation metrics between variations in specification values and variations in each of a plurality of device parameters of the optimized analog circuit design using the multidimensional simulation data stored in the circuit-simulation data database, (d) determining, from the sensitivity measures or correlation metrics and by numerically solving multi-variable dependency relationships encoded in the trained machine learning model, a set of device-parameter adjustments required to adjust one or more specification values of the optimized analog circuit design at the target PVT conditions, (e) generating, by applying the determined device-parameter adjustments to the optimized analog circuit design, adjusted specification values at the target PVT conditions via execution of the machine-learning inference model, (f) validating the adjusted specification values by comparing the adjusted specification values to the boundary conditions and determining whether the adjusted specification values satisfy the boundary conditions, and (g) generating, when the adjusted specification values satisfy the boundary conditions, a fine-tuning report identifying the adjusted device parameters and the validated specification values.

In some embodiments, the trained machine learning model generates uncertainty-aware predictions outputting both predicted values and confidence scores, and provides uncertainty quantification.

In some embodiments, the design space exploration comprises automatically generating performance limits by systematically varying device characteristics using vectorized computation and identifying boundary conditions where specifications transition from meeting to failing requirements.

In some embodiments, the dominant circuit components are determined by performing gradient-based or tree-boosted sensitivity analysis internal to the trained machine learning model to isolate dominant device parameters.

In some embodiments, the optimization algorithm enforces the boundary conditions by applying constraint-projection operations, rejecting candidate designs violating operational limits, and ensuring all candidates maintain device operation within safe operating areas across all PVT conditions. The optimization criteria comprise at least one criterion selected from: maximizing, minimizing, achieving target values, constraining within ranges, minimizing PVT variations, or optimizing weighted combinations of multiple performance specifications.

In some embodiments, the boundary values are validated by computing confidence intervals and determining satisfaction when predicted values with confidence intervals fall within permitted ranges. The convergence criterion comprises a deviation threshold within 1-5% relative to target specification values, a maximum number of iterations, a rate of change below a threshold, or satisfaction of all boundary conditions.

In some embodiments, the fine-tuning report comprises: (a) graphical visualizations of predicted relationships between device-parameter adjustments and circuit-performance metrics across target PVT conditions, (b) device-parameter values generating specification-value variations minimized across PVT corners, and (c) per-specification deviation metrics quantifying differences between target PVT and nominal specification values.

In some embodiments, the adjusted specification values are validated by computing a confidence interval for each predicted specification value and fine-tuning is considered successful when adjusted specification values with confidence intervals substantially match targeted specification values within the boundary conditions.

In some embodiments, the method comprises iteratively recomputing the device-parameter adjustments by repeatedly executing the trained machine-learning model until the adjusted specification values fall within a desired tolerance range across the range of PVT variations.

In some embodiments, the valid functional ranges are determined by performing preliminary simulations, verifying devices operate within operational limits, and establishing boundaries for random sampling.

In some embodiments, the machine learning model is trained by evaluating circuit characteristics, testing multiple algorithms on a validation subset, and selecting the algorithm achieving best predictive performance. The trained machine learning model comprises an ensemble of multiple algorithms providing uncertainty-aware predictions by outputting both a predicted value and a model-derived confidence score for each specification value.

In one aspect, a system for designing analog circuits using machine-learning models is provided. The system comprises one or more processors and one or more non-transitory memory components storing instructions that, when executed by the one or more processors, cause the system to: (a) generate one or more analog circuit configurations using at least one design tool, (b) evaluate each of the one or more analog circuit configurations using at least one simulation tool to determine which of the analog circuit configurations satisfy predefined specifications under nominal operating conditions, (c) select a base analog circuit configuration from among the analog circuit configurations that satisfy the predefined specifications, (d) determine, through preliminary simulation, valid functional ranges for device sizes, device parameters, input conditions, output conditions, and Process-Voltage-Temperature (PVT) conditions within which the base analog circuit configuration remains functional and all constituent devices operate within prescribed operational limits, (e) generate, using at least one random sampling method, a plurality of randomly generated combinations of device sizes, device parameters, input conditions, output conditions, and PVT conditions selected from within the determined valid functional ranges, (f) perform SPICE simulations on the selected base analog circuit configuration for each of the plurality of randomly generated combinations to obtain simulation data comprising measured performance specification values, (g) normalize and validate the simulation data using at least one data manipulation algorithm, (h) construct a training dataset from the normalized and validated simulation data, (i) train a machine-learning model using the constructed training dataset to generate a trained machine-learning model by (a) selecting a machine learning model suitable for the type of analog circuit configuration being designed, (b) optimizing hyperparameters of the machine learning model to minimize errors between predicted values and actual values, and (c) assessing performance of the trained machine learning model by determining a performance metric indicating predictive accuracy, (j) execute, using inference from the trained machine-learning model on the one or more processors, at least one of design space exploration, design optimization, or fine-tuning of the analog circuit configuration without reverting to SPICE simulation, and (k) generate a report for the analog circuit configuration based on results obtained from step (j).

In some embodiments, the system performs the design space exploration by: (a) identifying dominant circuit components by computing sensitivity measures or correlation metrics, (b) determining specification values using the trained machine learning model without SPICE simulation, (c) modifying device parameters, (d) iteratively repeating until convergence, and (e) generating a design space exploration report with graphical visualizations.

In some embodiments, the system performs the design optimization by: (a) receiving optimization criteria and boundary conditions, (b) generating candidate analog circuit designs, (c) determining boundary values using the trained machine learning model, (d) identifying an optimized design by numerically solving multi-variable dependency relationships, (e) validating boundary values, and (f) iteratively recomputing until convergence.

In some embodiments, the system performs fine-tuning by: (a) receiving an optimized analog circuit design comprising device-level parameters previously determined to satisfy nominal specification values across predefined PVT ranges, (b) receiving, via a user interface, fine-tuning criteria comprising target PVT conditions, target specification values, and boundary conditions defining permitted ranges for one or more specification values, (c) computing, by executing the trained machine learning model on the one or more processors, sensitivity measures or correlation metrics between variations in specification values and variations in each of a plurality of device parameters of the optimized analog circuit design using the multidimensional simulation data stored in the circuit-simulation data database, (d) determining, from the sensitivity measures or correlation metrics and by numerically solving multi-variable dependency relationships encoded in the trained machine learning model, a set of device-parameter adjustments required to adjust one or more specification values of the optimized analog circuit design at the target PVT conditions, (e) generating, by applying the determined device-parameter adjustments to the optimized analog circuit design, adjusted specification values at the target PVT conditions via execution of the machine-learning inference model, (f) validating the adjusted specification values by comparing the adjusted specification values to the boundary conditions and determining whether the adjusted specification values satisfy the boundary conditions, and (g) generating, when the adjusted specification values satisfy the boundary conditions, a fine-tuning report identifying the adjusted device parameters and the validated specification values.

In another aspect, a non-transitory computer-readable storage medium is provided for storing instructions that, when executed by one or more processors of a computing system comprising a machine-learning model and a circuit-simulation data database, cause the one or more processors to perform a method for designing analog circuits using machine learning models. The method comprising: (a) generating one or more analog circuit configurations using at least one design tool, (b) evaluating each of the one or more analog circuit configurations using at least one simulation tool to determine which analog circuit configurations meet predefined specifications under nominal conditions, (c) selecting a base analog circuit configuration from among the analog circuit configurations that meet the predefined specifications, (d) determining, through preliminary simulation, valid functional ranges for device sizes, device parameters, input conditions, output conditions, and Process, Voltage, and Temperature (PVT) conditions within which the base analog circuit configuration remains functional and all devices operate within operational limits, (e) generating, using at least one random sampling method, a plurality of randomly generated combinations of device sizes, device parameters, input conditions, output conditions, and PVT conditions selected from within the determined valid functional ranges, (f) performing SPICE simulations on the selected base analog circuit configuration for each of the plurality of randomly generated combinations to obtain simulation data comprising measured performance specification values, (g) normalizing and validating the simulation data using at least one data manipulation algorithm, (h) generating a training dataset from the normalized and validated simulation data, (i) training a machine learning model using the generated training dataset to generate a trained machine learning model, (j) performing at least one of design space exploration, design optimization, or fine-tuning of the analog circuit configuration using inference from the trained machine learning model executed on the one or more processors without reverting to SPICE simulation, and (k) generating a report for the analog circuit configuration based on results from step (j).

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates a block diagram of a system for designing analog circuits using machine-learning models according to some embodiments herein;

FIGS. 2A-2C are flow diagrams that illustrate a method for performing design space exploration (DSE) on analog circuits using a machine learning (ML) model according to some embodiments herein;

FIG. 3 illustrates a schematic diagram of a two-stage operational amplifier according to some embodiments herein;

FIG. 4A depicts a user interface view that illustrates a process of receiving nominal values for specifications of a two-stage operational amplifier from a user according to some embodiments herein;

FIG. 4B depicts a user interface view that illustrates predicted specifications of a two-stage operational amplifier based on user-selected values for process, voltage, temperature, and width, in accordance with some embodiments;

FIG. 5A is a graphical representation that illustrates an effect of differential pair width (W_{d}) on a direct current (DC) gain of an operational amplifier according to some embodiments herein;

FIG. 5B is a graphical representation that illustrates the effect of the differential pair width (W_{d}) on a phase margin of the operational amplifier according to some embodiments herein;

FIG. 5C is a graphical representation that illustrates the effect of the common mode transistor width (W_{cm1}) on the negative ICMR of the operational amplifier according to some embodiments herein;

FIG. 5D is a graphical representation that illustrates the effect of the common mode transistor width (W_{cm1}) on a Power supply rejection ratio (PSRR) of the operational amplifier according to some embodiments herein;

FIG. 5E is a graphical representation that illustrates the effect of transistor M6 width (W_{dt}) on the rise time of the operational amplifier according to some embodiments herein;

FIG. 5F is a graphical representation that illustrates the effect of transistor M6 width (W_{dt}) on the gain margin of the operational amplifier according to some embodiments herein;

FIGS. 6A-6D are flow diagrams that illustrate a method for optimizing analog circuits using a machine learning (ML) model according to some embodiments herein;

FIGS. 7A-7B are graphical representations that illustrate the accuracy of a machine learning model for a two-stage operational amplifier (opamp) trained on a dataset from SPICE simulations according to some embodiments herein;

FIG. 7C is a graphical representation that illustrates the accuracy of a machine learning model trained on a larger dataset from SPICE simulations according to some embodiments herein;

FIG. 8 is a flow diagram that illustrates a method for fine-tuning an optimized analog circuit design according to specific input and output criteria using a machine learning (ML) model according to some embodiments herein;

FIG. 9 shows a graphical user interface displaying the result of “fine-tuning” the output impedance of a SERDES transmitter for a specific set of PVT conditions, according to some embodiments herein;

FIGS. 10A & 10B illustrate a computer-implemented method for designing analog circuits using machine learning models according to some embodiments herein; and

FIG. 11 is a representative hardware environment for practicing the embodiments herein.

### DETAILED DESCRIPTION OF PREFERRED EMBODIMENTS

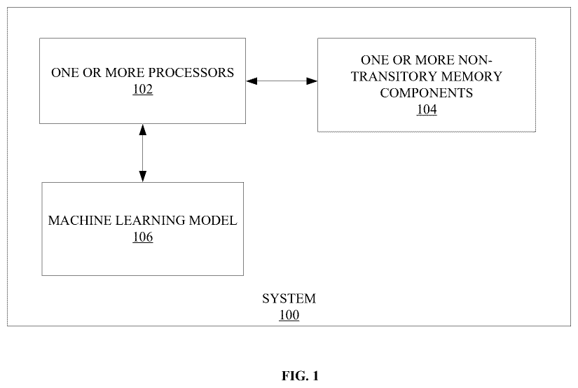

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Referring now to the drawings and more particularly to FIGS. 1 through 11, where similar reference characters denote corresponding features consistently throughout the figure's, preferred embodiments are shown.

FIG. 1 illustrates a block diagram of a system 100 for designing analog circuits using machine-learning models according to some embodiments herein. The system 100 (e.g., a computing device) includes one or more processors 102 that executes a machine learning model 106 and one or more non-transitory memory components 104 storing instructions. The system 100 executes the one or more processors 102. The one or more processors 102 is in communication with the machine-learning model 106 and a circuit-simulation data database. The one or more processors 102 generates one or more analog circuit configurations using at least one design tool. The one or more processors 102 evaluates each of the one or more analog circuit configurations using at least one simulation tool to determine which of the analog circuit configurations satisfy predefined specifications under nominal operating conditions. The one or more processors 102 selects a base analog circuit configuration from among the analog circuit configurations that satisfy the predefined specifications. The one or more processors 102 determines, through preliminary simulation, valid functional ranges for device sizes, device parameters, input conditions, output conditions, and Process-Voltage-Temperature (PVT) conditions within which the base analog circuit configuration remains functional and all constituent devices operate within prescribed operational limits. The one or more processors 102 generates, using at least one random sampling method, one or more randomly generated combinations of device sizes, device parameters, input conditions, output conditions, and PVT conditions selected from within the determined valid functional ranges. The one or more processors 102 performs SPICE simulations on the selected base analog circuit configuration for each of the one or more randomly generated combinations to obtain simulation data comprising measured performance specification values. The one or more processors 102 normalizes and validates the simulation data using at least one data manipulation algorithm. The one or more processors 102 validates the simulation data by applying at least one technique selected from z-score normalization, min-max scaling, or quantile transformation. The one or more processors 102 constructs a training dataset from the normalized and validated simulation data. The one or more processors 102 trains a machine-learning model 106 using the constructed training dataset to generate a trained machine-learning model. The system 100 executes, using inference from the trained machine-learning model 106 on the one or more processors 102, at least one of design space exploration, design optimization, or fine-tuning of the analog circuit configuration without reverting to SPICE simulation. The system 100 generates a report for the analog circuit configuration based on results.

In some embodiments, the report includes identified device parameters and optimized values, predicted specification values with confidence intervals, graphical visualizations across PVT conditions, sensitivity analysis results, and comparison metrics relative to initial specifications. The report further includes per-specification deviation metrics quantifying differences across PVT conditions, graphical visualizations of device-parameter relationships, and device-parameter values minimizing specification-value variations across PVT corners.

In some embodiments, the system 100 performs the design space exploration by: (a) identifying dominant circuit components by computing sensitivity measures or correlation metrics, (b) determining specification values using the trained machine learning model 106 without SPICE simulation, (c) modifying device parameters, (d) iteratively repeating until convergence, and (e) generating a design space exploration report with graphical visualizations.

In some embodiments, the system 100 performs the design optimization by: (a) receiving optimization criteria and boundary conditions, (b) generating candidate analog circuit designs, (c) determining boundary values using the trained machine learning model 106, (d) identifying an optimized design by numerically solving multi-variable dependency relationships, (e) validating boundary values, and (f) iteratively recomputing until convergence.

In some embodiments, the system 100 performs fine-tuning by: (a) receiving an optimized analog circuit design comprising device-level parameters previously determined to satisfy nominal specification values across predefined PVT ranges, (b) receiving, via a user interface, fine-tuning criteria comprising target PVT conditions, target specification values, and boundary conditions defining permitted ranges for one or more specification values, (c) computing, by executing the trained machine learning model 106 on the one or more processors 102, sensitivity measures or correlation metrics between variations in specification values and variations in each of a plurality of device parameters of the optimized analog circuit design using the multidimensional simulation data stored in the circuit-simulation data database, (d) determining, from the sensitivity measures or correlation metrics and by numerically solving multi-variable dependency relationships encoded in the trained machine learning model 106, a set of device-parameter adjustments required to adjust one or more specification values of the optimized analog circuit design at the target PVT conditions, (e) generating, by applying the determined device-parameter adjustments to the optimized analog circuit design, adjusted specification values at the target PVT conditions via execution of the machine-learning inference model, (f) validating the adjusted specification values by comparing the adjusted specification values to the boundary conditions and determining whether the adjusted specification values satisfy the boundary conditions, and (g) generating, when the adjusted specification values satisfy the boundary conditions, a fine-tuning report identifying the adjusted device parameters and the validated specification values.

In some embodiments, the machine learning model is trained by: (a) selecting a machine learning model suitable for the type of analog circuit configuration being designed, (b) optimizing hyperparameters of the machine learning model to minimize errors between predicted values and actual values, and (c) assessing performance of the trained machine learning model by determining a performance metric indicating predictive accuracy.

In some embodiments, the trained machine learning model generates uncertainty-aware predictions outputting both predicted values and confidence scores, and provides uncertainty quantification through ensemble-model variance, bootstrapped sampling, confidence intervals, or prediction intervals.

In some embodiments, the design space exploration comprises automatically generating performance limits by systematically varying device characteristics using vectorized computation and identifying boundary conditions where specifications transition from meeting to failing requirements.

In some embodiments, the dominant circuit components are determined by performing gradient-based or tree-boosted sensitivity analysis internal to the trained machine learning model to isolate dominant device parameters.

In some embodiments, the optimization algorithm enforces the boundary conditions by applying constraint-projection operations, rejecting candidate designs violating operational limits, and ensuring all candidates maintain device operation within safe operating areas across all PVT conditions. The optimization criteria comprise at least one criterion selected from: maximizing, minimizing, achieving target values, constraining within ranges, minimizing PVT variations, or optimizing weighted combinations of multiple performance specifications.

In some embodiments, the boundary values are validated by computing confidence intervals using ensemble-model variance or bootstrapped sampling and determining satisfaction when predicted values with confidence intervals fall within permitted ranges. The convergence criterion comprises a deviation threshold within 1-5% relative to target specification values, a maximum number of iterations, a rate of change below a threshold, or satisfaction of all boundary conditions.

In some embodiments, the fine-tuning report comprises (a) graphical visualizations of predicted relationships between device-parameter adjustments and circuit-performance metrics across target PVT conditions, (b) device-parameter values generating specification-value variations minimized across PVT corners, and (c) per-specification deviation metrics quantifying differences between target PVT and nominal specification values.

In some embodiments, the adjusted specification values are validated by computing a confidence interval for each predicted specification value using ensemble-model variance or bootstrapped sampling and fine-tuning is considered successful when adjusted specification values with confidence intervals substantially match targeted specification values within the boundary conditions.

In some embodiments, the system iteratively recomputing the device-parameter adjustments by repeatedly executing the trained machine-learning model until the adjusted specification values fall within a desired tolerance range across the range of PVT variations.

In some embodiments, the valid functional ranges are determined by performing preliminary simulations, verifying devices operate within operational limits, and establishing boundaries for random sampling.

In some embodiments, the machine learning model is trained by evaluating circuit characteristics, testing multiple algorithms on a validation subset, and selecting the algorithm achieving best predictive performance. The trained machine learning model comprises an ensemble of multiple algorithms providing uncertainty-aware predictions by outputting both a predicted value and a model-derived confidence score for each specification value.

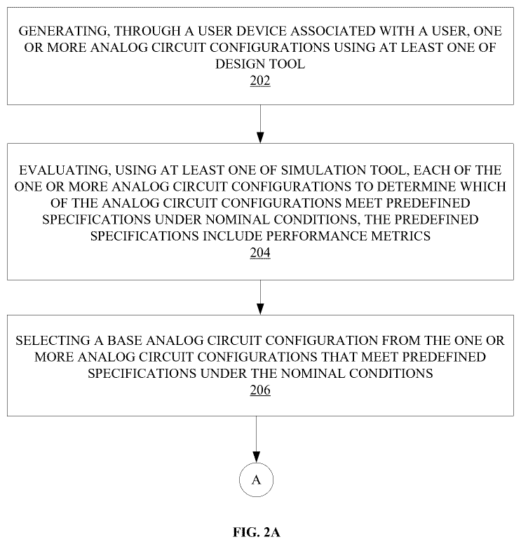

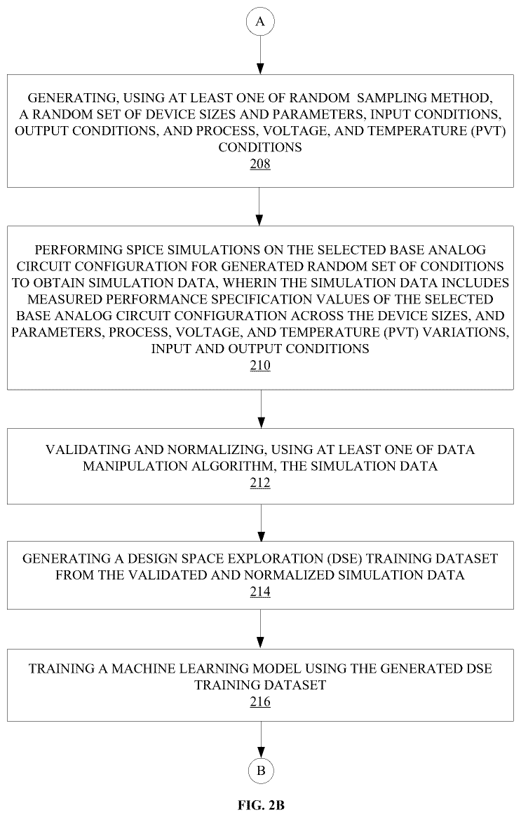

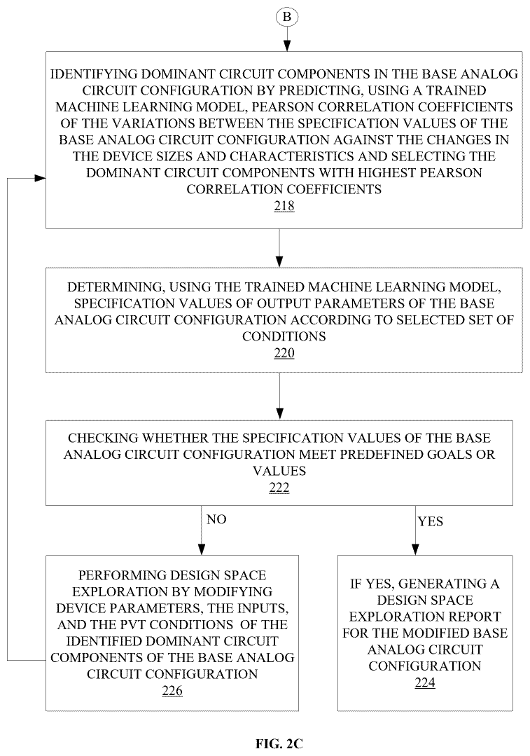

FIGS. 2A-2C are flow diagrams that illustrate a method for performing design space exploration (DSE) on analog circuits using a machine learning (ML) model according to some embodiments herein. At step 202, one or more analog circuit configurations are generated, through a user device associated with a user, using at least one of design tool. At step 204, each of the one or more analog circuit configurations are evaluated to determine which of the analog circuit configurations meets predefined specifications under nominal conditions, using at least one of simulation tool. The predefined specifications include performance metrics. At step 206, a base analog circuit configuration is selected from the one or more analog circuit configurations that meet predefined specifications under the nominal conditions. The base analog circuit configuration may be selected from the one or more analog circuit configurations that meet predefined specifications under worst-case and best-case conditions.

At step 208, a random set of device sizes and parameters, input conditions, output conditions, and process, voltage, and temperature (PVT) conditions are generated, using at least one of random sampling methods. The number of the random set ranges from at least 5,000 to 6,000. The sampling method may be but is not limited to, cluster sampling, stratified sampling, or 9-model sampling. At step 210, simulation data is obtained by running SPICE on the selected base analog circuit configuration. The simulation data includes measured performance specification values of the selected base analog circuit configuration across the range of device sizes and parameters, process, voltage, and temperature (PVT) variations, and input and output conditions.

At step 212, the simulation data is validated and refined/normalized using at least one of data manipulation algorithms by applying at least one technique selected from z-score normalization, min-max scaling, or quantile transformation. The simulation data is validated and normalized to check whether the simulation data is consistent with an expected circuit behaviour (actual value). At step 214, a design space exploration (DSE) training dataset is generated from the validated simulation. At step 216, the ML model is trained using the generated DSE training dataset to generate the trained machine learning model. A predictive performance of the trained machine learning model may be optimized using at least one of modeling techniques. The modeling techniques may be an open-source Categorical Boosting (CatBoos) algorithm. The CatBoost algorithm optimizes the parameters of the machine learning model to minimize errors between predicted and actual values.

In some embodiments, the method includes assessing a performance of the trained machine learning model by comparing inference data of the trained machine learning model with the SPICE simulation data under a range of sample conditions. The performance of the trained machine learning model is assessed using a metric of R² score. For example, if the R² score meets a predefined threshold (e.g., 0.99), it indicates a high level of accuracy in predicting the analog circuit's behavior.

The method for design space exploration and optimization utilizes inference from the ML model in a data domain. This demonstrates a performance that is orders of magnitude faster and more resource-efficient than conventional methods that depend on SPICE simulations conducted in the circuit domain.

Table 1 illustrates the run times of SPICE simulations and the inference times for 6,000 samples of input conditions across three representative analog circuits.

TABLE 1

| | SPICE | Inference time from | |
|---|---|---|---|
| | simulation run | Machine learning | Speed up |
| Circuit | time (sec) | models (sec) | factor |
| Folded cascode | 12,600 | 3.36 | 3,750 |
| op-amp | | | |
| Two-stage op-amp | 7,200 | 1.2 | 6,000 |
| 1 GHz low noise | 10,800 | 2.58 | 4,186 |
| amplifier | | | |

At step 218, dominant circuit components are determined in the base analog circuit configuration by predicting, using the trained machine learning model, the Pearson correlation coefficients of the variations in the specification values of the base analog circuit configuration against the changes in the device sizes or characteristics. The dominant circuit components that have the highest Pearson correlation coefficients may be selected. At step 220, the device sizes, input and output conditions, and the PVT conditions of the base analog circuit configuration are varied and inferred, using the ML model, specification values of output parameters of the base analog circuit configuration according to a selected set of conditions.

At step 222, it is checked whether the specification values of the output parameters of the base analog circuit configuration meet predefined goals or values. At step 224, if the specification values of the output parameters of the base analog circuit configuration meet predefined goals or values, a design space exploration report is generated for the base analog circuit configuration. The base analog circuit configuration is selected as it meets the predefined goals. The report includes the selected device sizes and the specification values of the base analog circuit configuration.

At step 226, if the specification values of the output parameters of the base analog circuit configuration do not meet predefined goals or values, the design space exploration is performed by modifying the device parameters of the identified dominant circuit components in the base analog circuit configuration, the inputs, and PVT conditions. Subsequently, the method loops back to the step 220 to infer the specification values of the output parameters of the base analog circuit configuration using the machine learning model.

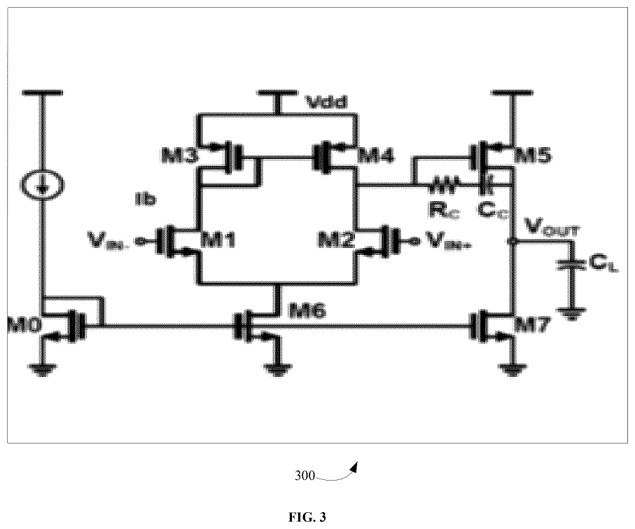

FIG. 3 illustrates a schematic diagram of a two-stage operational amplifier 300 according to some embodiments herein. The two-stage operational amplifier 300 is implemented in a 28 nm CMOS process. The performance of the two-stage amplifier 300 is determined by one or more parameters. The one or more parameters include input conditions PVT conditions, M1 and M2 width (w_{d}), M6 width (w_{dt}), M3, and M4 width (wcm1), M5 width (wₛ), M7 (wₛₜ), compensation Capacitor (Cc), compensation Resistor (Rc), and length of MOSFET's (L).

Table: 2 illustrates the input parameters along with their nominal values for the two-stage operational amplifier 300.

TABLE 2

| PARAMETERS | NOMINAL VALUES | |
|---|---|---|
| V_{dd} | 1.8 | V |
| TEMPERATURE | 27° | C. |
| PROCESS | TT CORNER | |
| M1, M2 WIDTH | 3 | μm |
| (W_{D}) | | |
| M6 WIDTH (W_{DT}) | 13 | μm |
| M3 AND M4 | 9 | μm |
| WIDTH (W_{CM1}) | | |
| M5 WIDTH (W_{S}) | 8 | μm |
| M7(W_{ST}) | 7 | μm |
| C_{C} | 0.7 | PF |
| R_{C} | 39 | kΩ |
| L (LENGTH OF | 1 | μ |

ALL MOSFET'S)

Table 2 illustrates the nominal/targeted values for the input parameters. The nominal values represent predefined initial conditions that are set by a user for the input parameters. For example, the V_{dd} is 1.8V, the temperature is 27° C., the process is Typical-Typical (TT), indicating the nominal process corner during fabrication, the M1, and M2 width is 3 μm, the M6 width is 13 μm, the M3, and M4 width is 9 μm, M5 width (ws) is 8 μm, the M7 (wst) is 7 μm, the Cc is 0.7 PF, the Rc is 39 kΩ, and the length of all MOSFETs (L) is 1.

Table: 3: illustrates the output parameters and their nominal specification values for the two-stage operational amplifier 300.

TABLE 3

| OUTPUT PERFORMANCES/ | |
|---|---|
| PARAMTER | NOMINAL SPEC(S) |
| SLEW RATE (V/μs) | 23.59 |
| SETTING TIME (ns) | 99.91 |
| ICMR+ (V) | 1.746 |
| ICMR (V) | 99.98n |
| POWER (μW) | 84.1 |
| PM (DEGREE) | 66.11 |
| GM (dB) | 29.3 |
| DC_GAIN (dB) | 77 |
| UGB (MHz) | 16.86 |
| PSRR (dB) | −9.774 |

The DSE method identifies dominant components in the two-stage operational amplifier 300. The DSE method computes, using the ML model, the specification values of the output parameters of the two-stage operational amplifier 300. The DSE method is performed by varying the characteristics. The characteristics include at least one of widths and gate lengths of MOS devices, values of resistors, values of capacitors, process corner, supply voltage, or temperature.

The DSE method infers the circuit specifications under predefined initial conditions and determines how their changes affect the analog circuit's specifications. At this step, various plots are created as graphic displays of such relationships to understand them. The DSE method also checks whether the specification values of the output parameters of the base analog circuit configuration meet predefined goals. There may be several variations of the base analog design with different device parameters that meet the predefined goals. These analog circuit configurations/designs are selected as the “best design candidates”.

The output parameters of the two-stage operational amplifier 300 are a slew rate (V/μs), settling time (ns), Input Common Mode Range (ICMR)+voltage (V), ICMR−(V), power (W), PM degree, GM (dB), DC_gain (dB), UGB (MHz), and PSRR (dB). The nominal specifications value is 23.59 for the slew rate (V/μs), 99.91 for the settling time (ns), 1.746 for the ICMR+(V), 99.98n ICMR−(V), 84.1 for the power (W), 66.11 for the PM (degree), 29.3 for GM (dB), 77 for the DC_gain (dB), 16.86 for the UGB (MHz), and −9.774 for the PSRR (dB).

The slew rate means the maximum rate at which the output voltage can change over time. The higher slew rate indicates that the amplifier responds more rapidly to changes in the input signals. The slew rate is 23.59 V/μs, meaning the output can change by up to 23.59 volts in one microsecond. The settling time is the time taken for the output to stabilize to 90% after a sudden change in input. The settling time is 99.91 ns, meaning the amplifier's output stabilizes and stops fluctuating within this time after a signal change. The positive Input Common Mode Range (ICMR+) defines the maximum input voltage for which the amplifier operates linearly. The ICMR+ is 1.746V, indicating that the input signal can go up to 1.746V without causing distortion. The Negative Input Common Mode Range (ICMR−) means the minimum input voltage at which the amplifier still functions correctly. The 99.98 nV means that the input can drop as low as 99.98 nanovolts while the two-stage operational amplifier 300 remains in its linear region. The power consumption refers to the total amount of electrical power the amplifier consumes during operation. The phase margin indicates how close the amplifier is to becoming unstable. It is measured in degrees and represents the difference between the phase shift and 180° at the point where the gain equals 1 (unity). The phase margin of 66.11° implies that the two-stage operational amplifier 300 has a good level of stability, as a margin above 45° is considered stable.

The gain margin is a measure of how much gain can increase before the amplifier becomes unstable. The gain margin of 29.3 dB means the two-stage operational amplifier 300 may handle an additional gain of 29.3 dB before instability occurs. The DC gain refers to the gain of the amplifier at very low (or zero) frequencies. The DC gain of 77 dB means that the amplifier can significantly amplify low-frequency or steady-state signals by 77 decibels. The Unity Gain Bandwidth (UGB) is the frequency at which the gain of the amplifier drops to 1 (unity gain). The UGB is 16.86 MHz, meaning that the two-stage operational amplifier 300 maintains a gain of 1 up to frequencies of 16.86 MHz The Power Supply Rejection Ratio (PSRR) measures how the two-stage operational amplifier 300 rejects variations in the power supply voltage. The PSRR of −9.774 dB means the two-stage operational amplifier 300 is extremely resistant to power supply fluctuations.

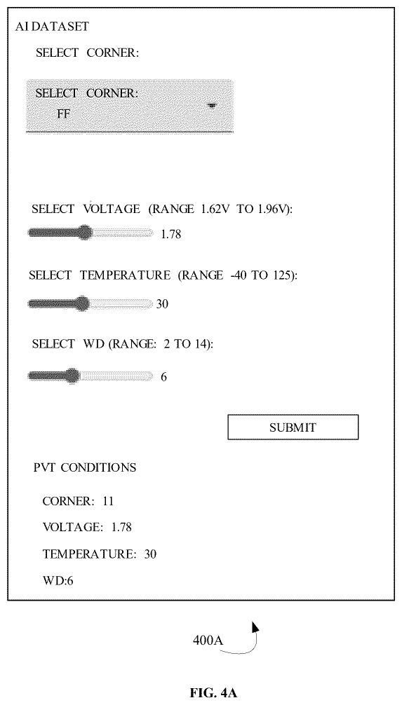

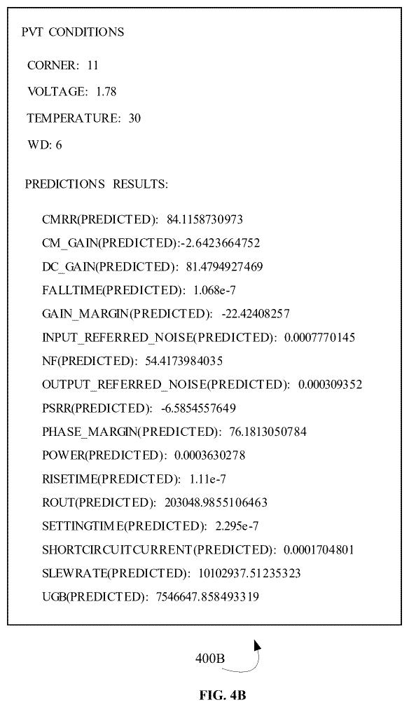

FIG. 4A depicts a user interface view 400A that illustrates a process of receiving nominal values for specifications of a two-stage operational amplifier from a user according to some embodiments herein. The user interface view 400A enables the user to input process, voltage temperature, and W_{d} width values for the two-stage operational amplifier. For example, the process may be Fast Fast (FF), the voltage is set at 1.78, the temperature at 30° C., and the width is 6 units.

FIG. 4B depicts a user interface view 400B that illustrates predicted specifications of a two-stage operational amplifier based on user-selected values for process, voltage, temperature, and width W_{d}, in accordance with some embodiments herein.

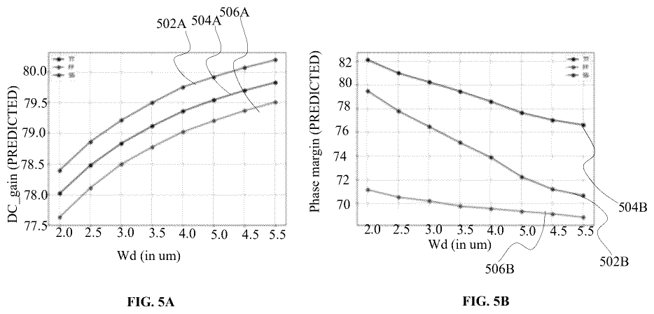

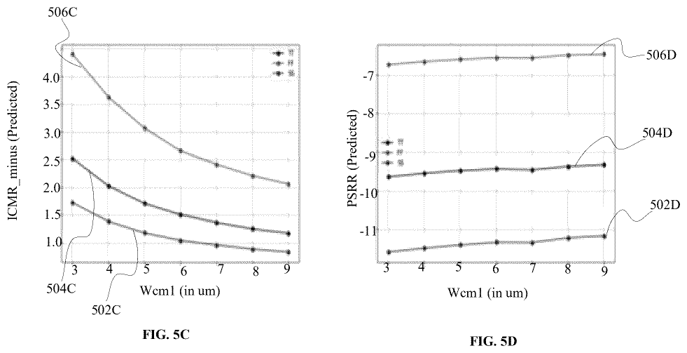

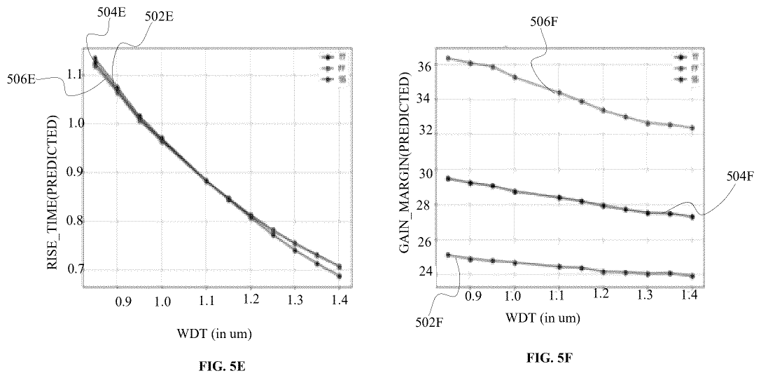

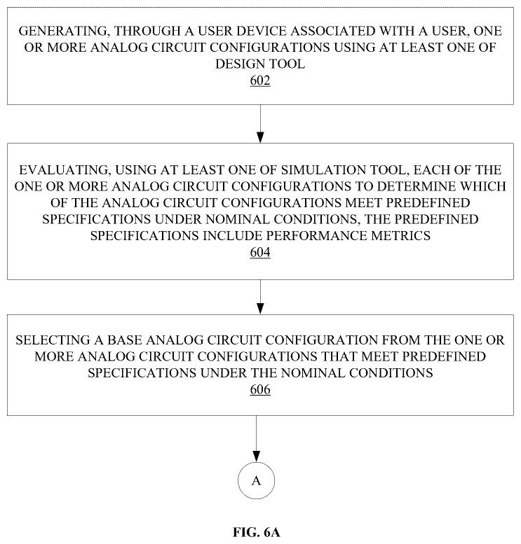

FIG. 5A is a graphical representation that illustrates an effect of differential pair width (W_{d}) on a direct current (DC) gain of an operational amplifier according to some embodiments herein. The graphical representation depicts width at the X-axis and predicted DC gain at the Y-axis. If a user selects a process corner as TT (typical-typical), as the width W_{d} of the differential pair increases, the predicted DC gain also increases as depicted at 502A. If the user selects the process corner as FF (fast-fast), as the width W_{d} of the differential pair increases, the predicted DC gain increases as depicted at 504A. If the user selects process corner SS (slow-slow), as the width W_{d} of the differential pair increases, the predicted DC gain increases as depicted at 506A. This indicates a positive correlation as wider differential pairs tend to produce higher DC gain. The graphical representation demonstrates the relationship between the width W_{d} of the input differential pair and the DC gain of the two-stage op-amp for the user to understand how adjusting the width affects gain under different process conditions.

FIG. 5B is a graphical representation that illustrates the effect of the differential pair width (W_{d}) on a phase margin of the operational amplifier according to some embodiments herein. The graphical representation depicts the width W_{d} at the X-axis and the predicted phase margin at the Y-axis. If a user selects a process corner as TT (typical-typical), as the width of the differential pair increases, the predicted phase margin decreases as depicted at 502B. If the user selects the process corner as FF (fast-fast), as the width W_{d} of the differential pair increases, the predicted phase margin decreases as depicted at 504B. If the user selects process corner SS (slow-slow), as the width W_{d} of the differential pair increases, the predicted phase margin decreases as depicted at 506B. The graphical representation demonstrates an inverse relationship, allowing the user to understand how changes in the width W_{d} impact the stability of the operational amplifier's performance under different process conditions.

FIG. 5C is a graphical representation that illustrates the effect of the common mode transistor width (W_{cm1}) on the negative ICMR of the operational amplifier according to some embodiments herein. The graphical representation depicts width (W_{cm1}) at the X-axis and predicted negative ICMR at the Y-axis. If a user selects the process corner as TT (typical-typical), as the width of the differential pair increases, the predicted negative ICMR decreases as depicted at 502C. If the user selects process corner as FF (fast-fast), as the width of the differential pair increases, the predicted negative ICMR decreases as depicted at 504C. If the user selects the process corner as SS (slow-slow), as the width of the differential pair increases, the predicted negative ICMR decreases as depicted at 506C.

FIG. 5D is a graphical representation that illustrates the effect of the common mode transistor width (W_{cm1}) on a Power supply rejection ratio (PSRR) of the operational amplifier according to some embodiments herein. The graphical representation depicts width (W_{cm1}) at the X-axis and predicted PSRR at the Y-axis. If a user selects the process corner as TT (typical-typical), as the width of the common mode transistor increases, the predicted PSRR increases as depicted at 502D. If the user selects the process corner as FF (fast-fast), as the width of the common mode transistor increases, the predicted PSRR increases as depicted at 504D. If the user selects the process corner as SS (slow-slow), as the width of the common mode transistor increases, the predicted PSRR increases as depicted at 506D.

FIG. 5E is a graphical representation that illustrates the effect of transistor M6 width (W_{dt}) on the rise time of the operational amplifier according to some embodiments herein. The graphical representation depicts the width at the X-axis and the predicted rise time at the Y-axis. If a user selects the process corner as TT (typical-typical), as the width of M6 increases, the predicted rise time decreases as depicted at 502E. If the user selects the process corner as FF (fast-fast), as the width of M6 increases, the predicted rise time decreases as depicted at 504E. If the user selects the process corner as SS (slow-slow), as the width of M6 increases, the predicted rise time decreases as depicted at 506E.

FIG. 5F is a graphical representation that illustrates the effect of transistor M6 width (W_{dt}) on the gain margin of the operational amplifier according to some embodiments herein. The graphical representation depicts the width at the X-axis and the predicted gain margin at the Y-axis. If a user selects the process corner as TT (typical-typical), as the width of M6 increases, the predicted gain margin decreases as depicted at 502F. If the user selects the process corner as FF (fast-fast), as the width M6 increases, the predicted gain margin decreases as depicted at 504F. If the user selects the process corner as SS (slow-slow), as the width of M6 increases, the predicted gain margin decreases as depicted at 506F.

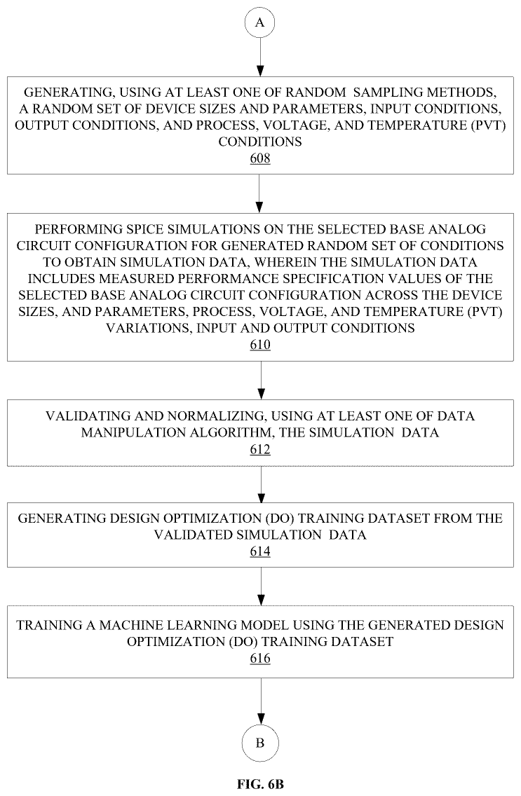

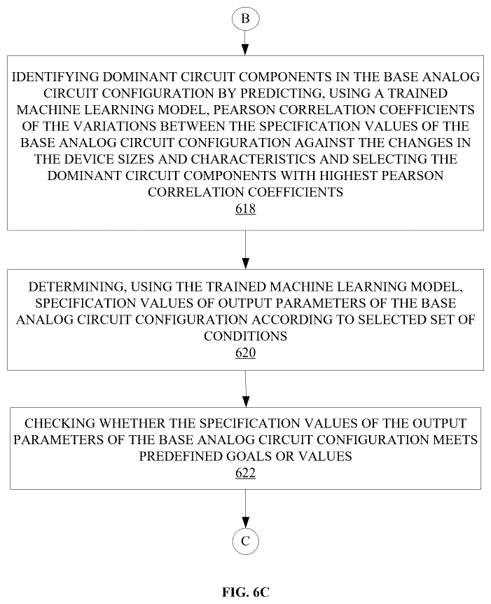

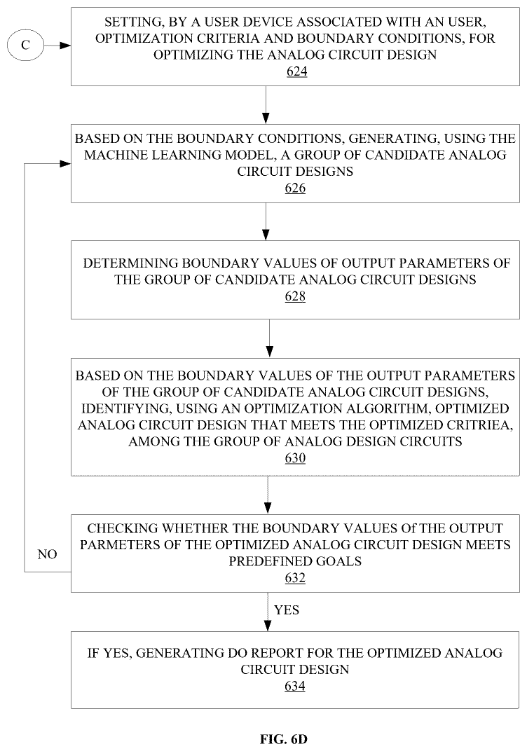

FIGS. 6A-6D are flow diagrams that illustrate a method for optimizing analog circuits using a machine learning (ML) model according to some embodiments herein. At step 602, one or more analog circuit configurations are generated, through a user device associated with a user, using at least one of design tool. At step 604, each of the one or more analog circuit configurations are evaluated, using at least one of simulation tool, to determine which of the analog circuit configurations meets predefined specifications under nominal conditions. The predefined specifications include performance metrics. At step 606, a base analog circuit configuration is selected from the one or more analog circuit configurations that meet predefined specifications under the nominal conditions.

At step 608, random set of device sizes and parameters, input conditions, output conditions, and process, voltage, and temperature (PVT) conditions are generated, using the at least one of the random sampling methods. The number of the random set ranges from at least 5,000 to 10,000.

At step 610, a Simulation Program with Integrated Circuit Emphasis (SPICE) simulations are performed on the selected base analog circuit configuration for each generated random set of device sizes, input, and PVT conditions to obtain simulation data. The simulation data includes measured performance specification values across the range of device sizes and parameters, process, voltage, and temperature (PVT) variations, and input and output conditions. At step 612, the simulation data is validated and refined/normalized using at least one data manipulation algorithm by applying at least one technique selected from z-score normalization, min-max scaling, or quantile transformation. The simulation data is validated amd normalized to check whether the simulation data is consistent with an expected circuit behaviour (actual value). At step 614, a design optimization (DO) training dataset is generated from the validated simulation data. At step 616, the ML model is trained using the generated DO training dataset.

At step 618, the dominant circuit components are identified in the base analog circuit configuration by predicting, using the trained ML model, the Pearson correlation coefficients of the variations in the specification values of the base analog circuit configuration against the changes in the device sizes or characteristics. At step 620, the specification values of output parameters of the base analog circuit configuration are inferred/determined using the trained ML model. At step 622, It is checking whether the specification values of the output parameters of the base analog circuit configuration meet predefined goals or values. At step 624, optimization criteria, and boundary conditions are set, by a user device associated with a user, for optimizing the analog circuit design. At step 626, a group of candidate analog circuit designs are generated based on the boundary conditions using the trained machine learning model. At step 628, boundary values of output parameters of the group of candidate analog circuit designs are determined.

At step 630, optimized circuit design that meets the optimized criteria, among the group of candidate analog circuit designs, are identified based on the boundary values of the output parameters of the group of candidate analog circuit designs. The optimized criteria may include at least one of certain defined scores, the highest or lowest values of certain specs, or the lowest range of spec variations over PVT. At step 632, it is checking whether the boundary values of the output parameters of the optimized analog circuit design meet predefined goals or not. If not, performs the step of 626. At step 634, if the boundary values of the output parameters of the optimized analog circuit design meet predefined goals, a design optimization (DO) report for the optimized analog circuit design is generated. The report includes the device sizes and the specifications of the optimized analog circuit.

| Wd | Wst | Wdt | Wcml | Ws | Rc | Cc |
|---|---|---|---|---|---|---|
| 3u | 7 μm | 13 μm | 9 μm | 8 μm | 39k | 0.7p |

| | NOMINAL | PVT RANGE | PVT DIFF. |
|---|---|---|---|
| PERFORMANCES | SPEC(S) | (MIN, MAX) | (MAX − MIN) |
| SLEWRATE(V/μs) | 23.59 | [17.54, 26.81] | 9.27 |
| SETTLINGTIME(ns) | 99.91n | [84.92, 101.8] | 16.88 |
| ICMR+(V) | 1.746 | [1.557, 1.799] | 0.242 |
| ICMR−(V) | 99.98n | [31.42n, 10.67μ] | 10.639μ |
| POWER(μW) | 84.1μ | [83.39μ, 84.73μ] | 1.34μ |
| PM(DEGREE) | 66.11 | [53.83, 67.55] | 13.72 |
| GM(dB) | 29.3 | [23.86, 36.08] | 12.22 |
| DC_GAIN(dB) | 77 | [75.72, 79.95] | 4.23 |
| UGB(MHz) | 16.86 | [12.13, 23.82] | 11.69 |
| PSRR(dB) | −9.774 | [−12.08, −6.295] | 5.785 |

TABLE 5

| Wd | Wst | Wdt | Wcml | Ws | Rc | Cc |
|---|---|---|---|---|---|---|
| 5.5u | 7 μm | 8.5 μm | 5 μm | 8 μm | 38k | 0.8p |

| | NOMINAL | PVT RANGE | PVT DIFF. |
|---|---|---|---|
| PERFORMANCES | SPEC(S) | (MIN, MAX) | (MAX − MIN) |
| SLEWRATE(V/μs) | 14.06 | [11.53, 14.33] | 2.8 |
| SETTLINGTIME(ns) | 159 | [145.4, 159] | 13.6 |
| ICMR+(V) | 1.74 | [1.548, 1.8] | 0.252 |
| ICMR−(V) | 178.5n | [42.83n, 18.73μ] | 18μ |
| POWER(μW) | 73.75μ | [73.09, 74.32] | 1.23 |
| PM(DEGREE) | 71.08 | [59.03, 71.47] | 12.44 |
| GM(dB) | 29.03 | [24.07, 34.08] | 10.01 |
| DC_GAIN(dB) | 79.84 | [78.14, 81.11] | 2.97 |
| UGB(MHz) | 14.93 | [11.37, 20.76] | 9.39 |
| PSRR(dB) | −9.213 | [−12.09, −5.704] | 6.386 |

Table 4 presents the ranges over PVT and nominal specifications for the two-stage operational amplifier. Through the optimization process, a new design is generated with adjusted device sizes and specification ranges, as shown in Table 5. The optimization algorithm increases DC gain, increases phase margin, and reduces power consumption while ensuring that all other specifications remain within acceptable limits across the Process, Voltage, and Temperature (PVT) range. In the optimized design, the two-stage operational amplifier width Wd is increased from 3 μm (101) to 5.5 μm (103). The DC gain is improved from 77 dB to 79.84 dB, the phase margin is improved from 66.11 degrees to 71.08 degrees, and power consumption is reduced from 84.1 μW to 73.75 μW. Furthermore, the variations in DC gain and phase margin across PVT are minimized.

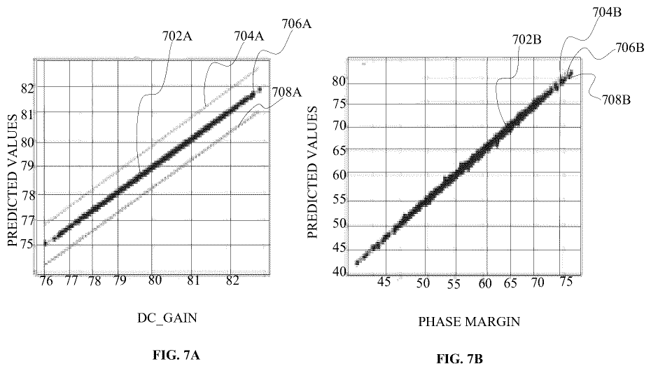

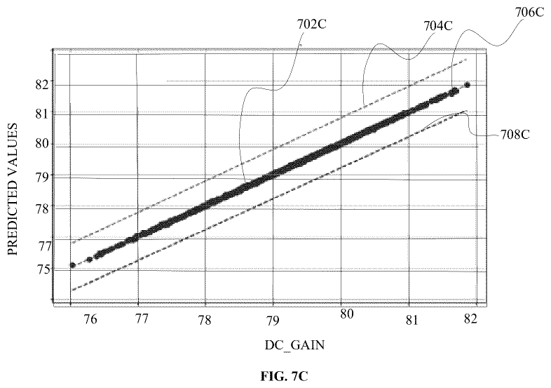

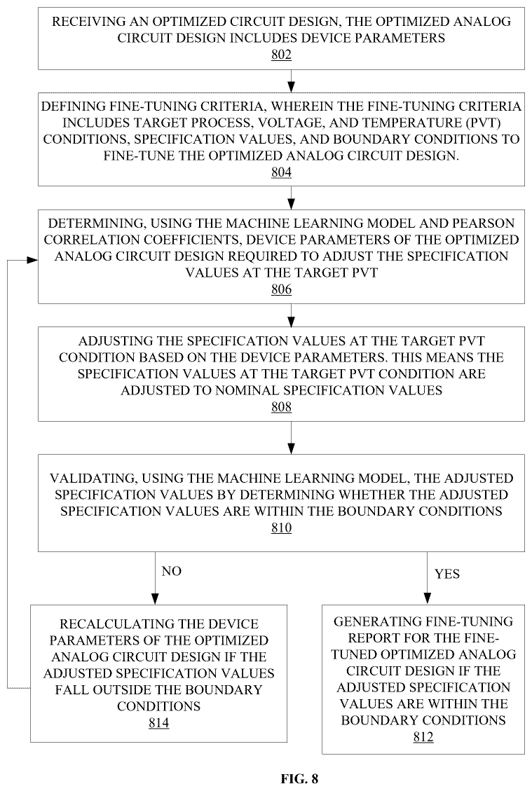

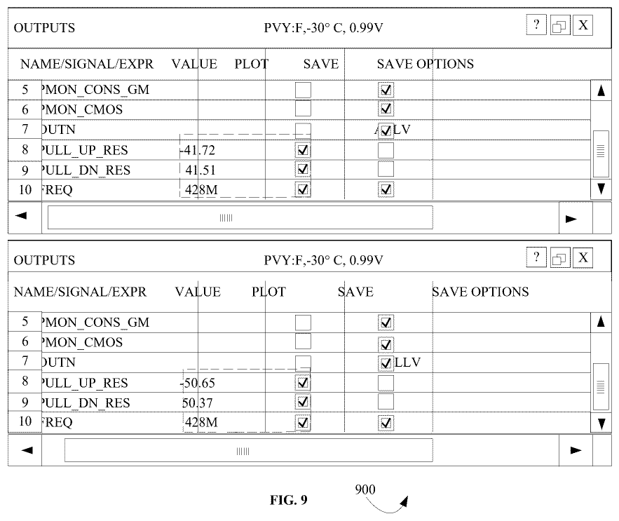

FIGS. 7A and 7B are graphical representations that illustrate the accuracy of a machine learning model for a two-stage operational amplifier (opamp) according to some embodiments herein. The machine learning model is trained on 6,000 data points from SPICE simulations using the CatBoost algorithm. In FIGS. 7A and 7B, the model's predictions for DC gain and phase margin are compared with actual SPICE simulation results for a test set of 1,000 samples. The scatter plots display the predicted versus actual values for these metrics, demonstrating a nearly 100% match that confirms that the ML model reliably replicates the SPICE results, even with a relatively modest amount of training data. The scatter plots in FIGS. 7A and 7B validate that the model trained with a relatively small amount of data (6,000 points) provides an accurate representation of the opamp's performance, enabling reliable predictions for key parameters.

The x-axis of FIG. 7A represents actual DC gain values in dB obtained from SPICE simulations. The y-axis of FIG. 7A represents the predicted DC Gain values generated by the machine learning model. The line of equality is illustrated at 706A, indicating the condition where the predicted DC gain matches the actual DC gain (i.e., predicted value=actual value) at 702A. The graphical representation depicts 99% and 101% of the actual DC gain values at 704A and 708A. The 99% and 101% of the actual DC gain values at 704A and 708A indicate an acceptable margin of error for the machine learning model predictions.

The x-axis of FIG. 7B represents the actual phase margin values obtained from SPICE simulations. The y-axis of FIG. 7B represents the predicted phase margin values predicted by the machine learning model. The graphical representation depicts a line of equality at 706B indicating the condition where the predicted phase margin exactly matches the actual phase margin (i.e., predicted value=actual value) at 702B. Points that lie on this line signify perfect predictive accuracy. The graphical representation represents two horizontal bands established around the line of equality, corresponding to 99% and 101% of the actual phase margin values at 704B and 708B. The graphical representation indicates the vast majority of data points are observed to lie within the defined accuracy bands of 99% and 101%. The machine learning model effectively predicts the phase margin for most test samples, reflecting a high level of accuracy and reliability in its predictions. The graphical representation indicates few data points extend beyond the 99% and 101% accuracy bands, indicating few instances where the predicted phase margin values deviate from the actual values by more than 1%.

FIG. 7C is a graphical representation that illustrates a machine learning model trained on a larger dataset from SPICE simulations according to some embodiments herein. The large dataset includes 45,026 data points. The graphical representation for DC gain in FIG. 7C is nearly indistinguishable from FIG. 7A, meaning that the model's accuracy is consistent across the two different dataset sizes.

The results in FIGS. 7A-7C illustrates the machine learning model is highly effective for large-scale design evaluations, as it maintains accuracy while drastically reducing computation time. The accuracy of the machine learning model (R2Score) is 0.9999, the mean error of the machine learning model is 0.0034, % and the standard deviation of error of the machine learning model is 0.0039.

FIG. 8 is a flow diagram that illustrates a method for fine-tuning an optimized analog circuit design according to specific criteria using a machine learning (ML) model according to some embodiments herein. At step, 802, an optimized analog circuit design is received. The optimized analog circuit design includes device parameters as shown in table:5. At step, 804, fine-tuning criteria is defined. The fine-tuning criteria include target Process, Voltage, and Temperature (PVT) conditions, specification values, and boundary conditions provided by a user to fine-tune the optimized analog circuit design. At step, 806, values of the device parameters of the optimized analog circuit design is determined to adjust the specification values at the target PVT using the machine learning model and Pearson correlation coefficients. At step, 808, the specification values at the target PVT condition are adjusted based on the calculated device parameters. This means the specification values at the target PVT condition are adjusted to nominal specification values. At step, 810, the adjusted specification values are validated by determining whether the adjusted specification values are within the boundary conditions using the machine learning model. At step, 812, a fine-tuning report is generated for the fine-tuned optimized analog circuit design if the adjusted specification values are within the boundary conditions. At step 814, the device parameters of the optimized analog circuit design is recalculated if the adjusted specification values fall outside the boundary conditions. This means repeating the fine-tuning step of 806 until the specification values at the target PVT condition are substantially equal to the nominal values within the boundaries.

FIG. 9 shows a graphical user interface 900 displaying the result of “fine-tuning” the output impedance of a SERDES transmitter for a specific set of PVT conditions according to some embodiments herein. The graphical user interface 900 illustrates the PVT conditions, which include the process corner, supply voltage, and temperature. The process corner is set to FF, the supply voltage is 0.99V, and the temperature is −30° C. Under the PVT conditions, the output impedances for both the NMOS and the PMOS drivers are 20% lower than the nominal value of 50 ohms. After fine-tuning, the output impedances are adjusted to within 2% of the 50 ohms nominal value. The results of the fine-tuning include a trim code, a fine-tuning circuit, and a control circuit.

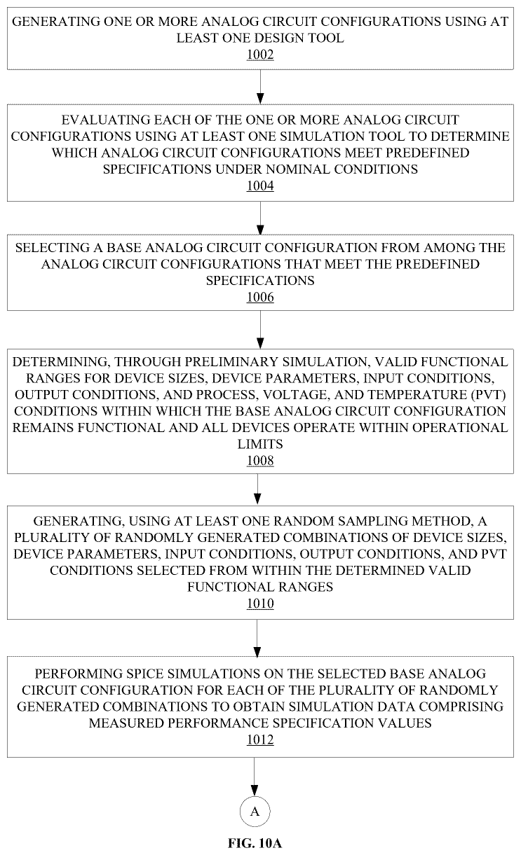

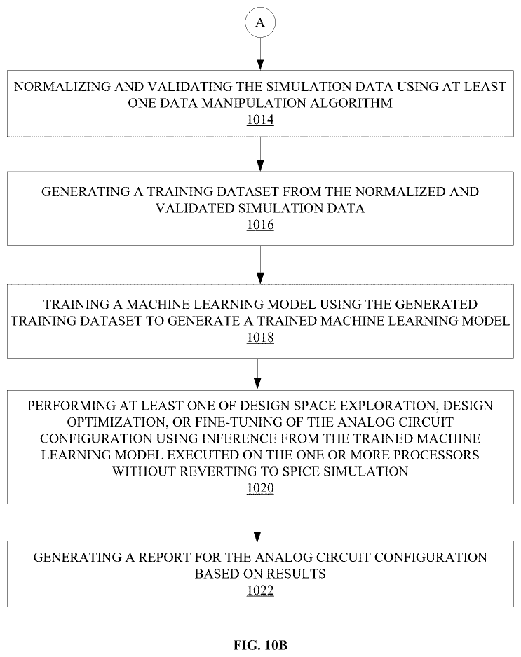

FIGS. 10A & 10B illustrate a computer-implemented method for designing analog circuits using machine learning models according to some embodiments herein. The method is executed by one or more processors of a computing system in communication with a machine-learning model and a circuit-simulation data database. At step 1002, one or more analog circuit configurations are generated using at least one design tool. At step 1004, each of the one or more analog circuit configurations are evaluated using at least one simulation tool to determine which analog circuit configurations meet predefined specifications under nominal conditions. At step 1006, a base analog circuit configuration is selected from among the analog circuit configurations that meet the predefined specifications. At step 1008, valid functional ranges are determined, through preliminary simulation, for device sizes, device parameters, input conditions, output conditions, and Process, Voltage, and Temperature (PVT) conditions within which the base analog circuit configuration remains functional and all devices operate within operational limits. At step 1010, one or more randomly generated combinations are generated for device sizes, device parameters, input conditions, output conditions, and PVT conditions selected from within the determined valid functional ranges, using at least one random sampling method. At step 1012, SPICE simulations are performed on the selected base analog circuit configuration for each of the one or more randomly generated combinations to obtain simulation data comprising measured performance specification values. At step 1014, the simulation data is normalized and validated using at least one data manipulation algorithm by applying at least one technique selected from z-score normalization, min-max scaling, or quantile transformation. At step 1016, a training dataset is generated from the normalized and validated simulation data. At step 1018, a machine learning model is trained using the generated training dataset to generate a trained machine learning model. At step 1020, at least one of design space exploration, design optimization, or fine-tuning of the analog circuit configuration is performed using inference from the trained machine learning model executed on the one or more processors without reverting to SPICE simulation. At step 1022, a report for the analog circuit configuration is generate based on the results.

In some embodiments, the simulation data is validated by applying at least one technique selected from z-score normalization, min-max scaling, or quantile transformation

In some embodiments, the report includes identified device parameters and optimized values, predicted specification values with confidence intervals, graphical visualizations across PVT conditions, sensitivity analysis results, and comparison metrics relative to initial specifications. The report further includes per-specification deviation metrics quantifying differences across PVT conditions, graphical visualizations of device-parameter relationships, and device-parameter values minimizing specification-value variations across PVT corners.

In some embodiments, the machine learning model is trained by: (a) selecting a machine learning model suitable for the type of analog circuit configuration being designed, (b) optimizing hyperparameters of the machine learning model to minimize errors between predicted values and actual values, and (c) assessing performance of the trained machine learning model by determining a performance metric indicating predictive accuracy.

In some embodiments, the step of performing design space exploration comprises: (a) identifying dominant circuit components by computing sensitivity measures or correlation metrics, (b) determining specification values using the trained machine learning model without SPICE simulation, (c) modifying device parameters, (d) iteratively repeating until convergence, and (e) generating a design space exploration report with graphical visualizations.

In some embodiments, the step of performing design optimization comprises: (a) receiving optimization criteria and boundary conditions, (b) generating candidate analog circuit designs, (c) determining boundary values using the trained machine learning model, (d) identifying an optimized design by numerically solving multi-variable dependency relationships, (e) validating boundary values, and (f) iteratively recomputing until convergence.

In some embodiments, the step of performing fine-tuning comprises: (a) receiving an optimized analog circuit design comprising device-level parameters previously determined to satisfy nominal specification values across predefined PVT ranges, (b) receiving, via a user interface, fine-tuning criteria comprising target PVT conditions, target specification values, and boundary conditions defining permitted ranges for one or more specification values, (c) computing, by executing the trained machine learning model on the one or more processors, sensitivity measures or correlation metrics between variations in specification values and variations in each of a plurality of device parameters of the optimized analog circuit design using the multidimensional simulation data stored in the circuit-simulation data database, (d) determining, from the sensitivity measures or correlation metrics and by numerically solving multi-variable dependency relationships encoded in the trained machine learning model, a set of device-parameter adjustments required to adjust one or more specification values of the optimized analog circuit design at the target PVT conditions, (e) generating, by applying the determined device-parameter adjustments to the optimized analog circuit design, adjusted specification values at the target PVT conditions via execution of the machine-learning inference model, (f) validating the adjusted specification values by comparing the adjusted specification values to the boundary conditions and determining whether the adjusted specification values satisfy the boundary conditions, and (g) generating, when the adjusted specification values satisfy the boundary conditions, a fine-tuning report identifying the adjusted device parameters and the validated specification values.

In some embodiments, the trained machine learning model generates uncertainty-aware predictions outputting both predicted values and confidence scores, and provides uncertainty quantification through ensemble-model variance, bootstrapped sampling, confidence intervals, or prediction intervals.

In some embodiments, the design space exploration comprises automatically generating performance limits by systematically varying device characteristics using vectorized computation and identifying boundary conditions where specifications transition from meeting to failing requirements.

In some embodiments, the dominant circuit components are determined by performing gradient-based or tree-boosted sensitivity analysis internal to the trained machine learning model to isolate dominant device parameters.

In some embodiments, the optimization algorithm enforces the boundary conditions by applying constraint-projection operations, rejecting candidate designs violating operational limits, and ensuring all candidates maintain device operation within safe operating areas across all PVT conditions. The optimization criteria comprise at least one criterion selected from: maximizing, minimizing, achieving target values, constraining within ranges, minimizing PVT variations, or optimizing weighted combinations of multiple performance specifications.

In some embodiments, the boundary values are validated by computing confidence intervals using ensemble-model variance or bootstrapped sampling and determining satisfaction when predicted values with confidence intervals fall within permitted ranges. The convergence criterion comprises a deviation threshold within 1-5% relative to target specification values, a maximum number of iterations, a rate of change below a threshold, or satisfaction of all boundary conditions.

In some embodiments, the fine-tuning report comprises: (a) graphical visualizations of predicted relationships between device-parameter adjustments and circuit-performance metrics across target PVT conditions, (b) device-parameter values generating specification-value variations minimized across PVT corners, and (c) per-specification deviation metrics quantifying differences between target PVT and nominal specification values.

In some embodiments, the adjusted specification values are validated by computing a confidence interval for each predicted specification value using ensemble-model variance or bootstrapped sampling and fine-tuning is considered successful when adjusted specification values with confidence intervals substantially match targeted specification values within the boundary conditions.

In some embodiments, the method comprises iteratively recomputing the device-parameter adjustments by repeatedly executing the trained machine-learning model until the adjusted specification values fall within a desired tolerance range across the range of PVT variations.

In some embodiments, the valid functional ranges are determined by performing preliminary simulations, verifying devices operate within operational limits, and establishing boundaries for random sampling.

In some embodiments, the machine learning model is trained by evaluating circuit characteristics, testing multiple algorithms on a validation subset, and selecting the algorithm achieving best predictive performance. The trained machine learning model comprises an ensemble of multiple algorithms providing uncertainty-aware predictions by outputting both a predicted value and a model-derived confidence score for each specification value.

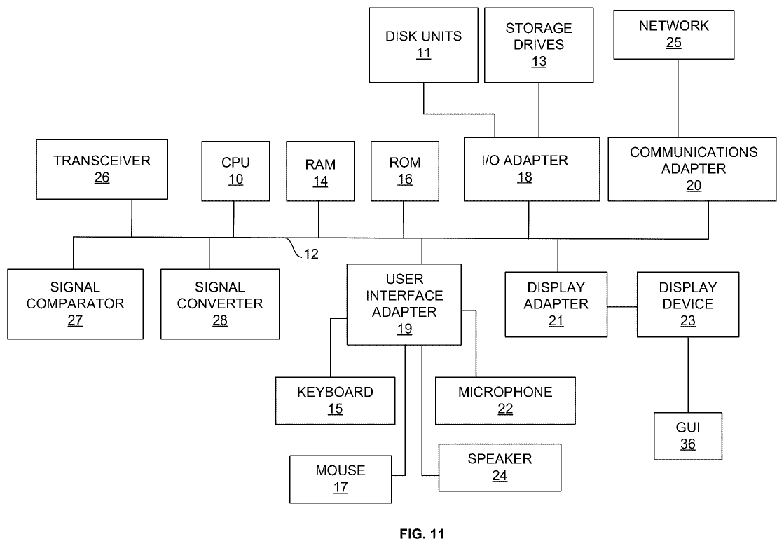

FIG. 11 is a representative hardware environment for practicing the embodiments herein. The various systems and corresponding components described herein and/or illustrated in the figures may be embodied as hardware-enabled modules and maybe one or more overlapping or independent electronic circuits, devices, and discrete elements packaged onto a circuit board to provide data and signal processing functionality within a computer. An example might be a comparator, inverter, or flip-flop, which could include one or more transistors and other supporting devices and circuit elements. The systems that include electronic circuits process computer logic instructions capable of providing digital and/or analog signals for performing various functions as described herein. The various functions can further be embodied and physically saved as any of data structures, data paths, data objects, data object models, object files, and database components. For example, the data objects could include a digital packet of structured data. Example data structures may include any of an array, tuple, map, union, variant, set, graph, tree, node, or object, which may be stored and retrieved by computer memory and may be managed by processors, compilers, and other computer hardware components. The data paths can be part of a computer CPU or GPU that performs operations and calculations as instructed by the computer logic instructions. The data paths could include digital electronic circuits, multipliers, registers, and buses capable of performing data processing operations and arithmetic operations (e.g., Add, Subtract, etc.), bitwise logical operations (AND, OR, XOR, etc.), bit shift operations (e.g., arithmetic, logical, rotate, etc.), complex operations (e.g., using single clock calculations, sequential calculations, iterative calculations, etc.). The data objects may be physical locations in computer memory and can be a variable, a data structure, or a function. Some examples of the modules include relational databases (e.g., such as Oracle® relational databases), and the data objects can be a table or column, for example. Other examples include specialized objects, distributed objects, object-oriented programming objects, and semantic web objects. The data object models can be an application programming interface for creating Hypertext Markup Language (HTML) and Extensible Markup Language (XML) electronic documents. The models can be any of a tree, graph, container, list, map, queue, set, stack, and variations thereof, according to some examples. The data object files can be created by compilers and assemblers and contain generated binary code and data for a source file. The database components can include any of tables, indexes, views, stored procedures, and triggers.

In an example, the embodiments herein can provide a computer program product configured to include a pre-configured set of instructions, which when performed, can result in actions as stated in conjunction with various figures herein. For example, the pre-configured set of instructions can be stored on a tangible non-transitory computer-readable medium. For example, the tangible non-transitory computer-readable medium can be configured to include the set of instructions, which when performed by a device, can cause the device to perform acts similar to the ones described here.

The embodiments herein may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as discussed above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or a combination thereof) to a computer, the computer properly views the connection as a computer-readable medium. Thus, any such connection is properly termed a computer-readable medium. Combinations of the above should also be included within the scope of the computer-readable media.

For example, computer-executable instructions include instructions and data that cause a special-purpose computer or special-purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Furthermore, the embodiments herein can take the form of a computer program product accessible from a computer-usable or computer-readable medium providing program code for use by or in connection with a computer or any instruction execution system. For the purposes of this description, a computer-usable or computer-readable medium can be any apparatus that can comprise, store, communicate, propagate, or transport the program for use by or in connection with the instruction execution system, apparatus, or device.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A computer-implemented method for designing analog circuits using machine learning models, the method executed by one or more processors of a computing system in communication with a machine-learning model and a circuit-simulation data database, wherein the method comprises:
(a) generating one or more analog circuit configurations using at least one design tool;
(b) evaluating each of the one or more analog circuit configurations using at least one simulation tool to determine which analog circuit configurations meet predefined specifications under nominal conditions;
(c) selecting a base analog circuit configuration from among the analog circuit configurations that meet the predefined specifications;
(d) determining, through preliminary simulation, valid functional ranges for device sizes, device parameters, input conditions, output conditions, and Process, Voltage, and Temperature (PVT) conditions within which the base analog circuit configuration remains functional and all devices operate within operational limits;
(e) generating, using at least one random sampling method, a plurality of randomly generated combinations of device sizes, device parameters, input conditions, output conditions, and PVT conditions selected from within the determined valid functional ranges;
(f) performing SPICE simulations on the selected base analog circuit configuration for each of the plurality of randomly generated combinations to obtain simulation data comprising measured performance specification values;
(g) normalizing and validating the simulation data using at least one data manipulation algorithm;
(h) generating a training dataset from the normalized and validated simulation data;
(i) training a machine learning model using the generated training dataset to generate a trained machine learning model;
(j) performing at least one of design space exploration, design optimization, or fine-tuning of the analog circuit configuration using inference from the trained machine learning model executed on the one or more processors without reverting to SPICE simulation; and
(k) generating a report for the analog circuit configuration based on results from step (j).

2. The method of claim 1, wherein the machine learning model is trained by:
selecting a machine learning model suitable for the type of analog circuit configuration being designed;
optimizing hyperparameters of the machine learning model to minimize errors between predicted values and actual values; and
assessing performance of the trained machine learning model by determining a performance metric indicating predictive accuracy.

3. The method of claim 1, wherein the step of performing design space exploration comprises:
(a) identifying dominant circuit components by computing sensitivity measures or correlation metrics;
(b) determining specification values using the trained machine learning model without SPICE simulation;
(c) modifying device parameters;
(d) iteratively repeating until convergence; and
(e) generating a design space exploration report with graphical visualizations.

4. The method of claim 1, wherein the step of performing design optimization comprises:
(a) receiving optimization criteria and boundary conditions;
(b) generating candidate analog circuit designs;
(c) determining boundary values using the trained machine learning model;
(d) identifying an optimized design by numerically solving multi-variable dependency relationships;
(e) validating boundary values; and
(f) iteratively recomputing until convergence.

5. The method of claim 1, wherein the step of performing fine-tuning comprises:
(a) receiving an optimized analog circuit design comprising device-level parameters previously determined to satisfy nominal specification values across predefined PVT ranges;
(b) receiving, via a user interface, fine-tuning criteria comprising target PVT conditions, target specification values, and boundary conditions defining permitted ranges for one or more specification values;
(c) computing, by executing the trained machine learning model on the one or more processors, sensitivity measures or correlation metrics between variations in specification values and variations in each of a plurality of device parameters of the optimized analog circuit design using the multidimensional simulation data stored in the circuit-simulation data database;
(d) determining, from the sensitivity measures or correlation metrics and by numerically solving multi-variable dependency relationships encoded in the trained machine learning model, a set of device-parameter adjustments required to adjust one or more specification values of the optimized analog circuit design at the target PVT conditions;
(e) generating, by applying the determined device-parameter adjustments to the optimized analog circuit design, adjusted specification values at the target PVT conditions via execution of the machine-learning inference model;
(f) validating the adjusted specification values by comparing the adjusted specification values to the boundary conditions and determining whether the adjusted specification values satisfy the boundary conditions; and
(g) generating, when the adjusted specification values satisfy the boundary conditions, a fine-tuning report identifying the adjusted device parameters and the validated specification values.

6. The method of claim 1, wherein the trained machine learning model generates uncertainty-aware predictions outputting both predicted values and confidence scores, and provides uncertainty quantification.

7. The method of claim 3, wherein the design space exploration comprises automatically generating performance limits by systematically varying device characteristics using vectorized computation and identifying boundary conditions where specifications transition from meeting to failing requirements.

8. The method of claim 3, wherein the dominant circuit components are determined by performing gradient-based or tree-boosted sensitivity analysis internal to the trained machine learning model to isolate dominant device parameters.

9. The method of claim 4, wherein the optimization algorithm enforces the boundary conditions by applying constraint-projection operations, rejecting candidate designs violating operational limits, and ensuring all candidates maintain device operation within safe operating areas across all PVT conditions, wherein the optimization criteria comprise at least one criterion selected from: maximizing, minimizing, achieving target values, constraining within ranges, minimizing PVT variations, or optimizing weighted combinations of multiple performance specifications.

10. The method of claim 4, wherein the boundary values are validated by computing confidence intervals and determining satisfaction when predicted values with confidence intervals fall within permitted ranges, wherein the convergence criterion comprises a deviation threshold within 1-5% relative to target specification values, a maximum number of iterations, a rate of change below a threshold, or satisfaction of all boundary conditions.

11. The method of claim 5, wherein the fine-tuning report comprises: (a) graphical visualizations of predicted relationships between device-parameter adjustments and circuit-performance metrics across target PVT conditions; (b) device-parameter values generating specification-value variations minimized across PVT corners; and (c) per-specification deviation metrics quantifying differences between target PVT and nominal specification values.

12. The method of claim 5, wherein the adjusted specification values are validated by computing a confidence interval for each predicted specification value and wherein fine-tuning is considered successful when adjusted specification values with confidence intervals substantially match targeted specification values within the boundary conditions.

13. The method of claim 5, wherein the method comprises iteratively recomputing the device-parameter adjustments by repeatedly executing the trained machine-learning model until the adjusted specification values fall within a desired tolerance range across the range of PVT variations.

14. The method of claim 1, wherein the valid functional ranges are determined by performing preliminary simulations, verifying devices operate within operational limits, and establishing boundaries for random sampling.

15. The method of claim 2, wherein the machine learning model is trained by evaluating circuit characteristics, testing multiple algorithms on a validation subset, and selecting the algorithm achieving best predictive performance, wherein the trained machine learning model comprises an ensemble of multiple algorithms providing uncertainty-aware predictions by outputting both a predicted value and a model-derived confidence score for each specification value.

16. A system for designing analog circuits using machine-learning models, the system comprising one or more processors and one or more non-transitory memory components storing instructions that, when executed by the one or more processors, cause the system to:
(a) generate one or more analog circuit configurations using at least one design tool;
(b) evaluate each of the one or more analog circuit configurations using at least one simulation tool to determine which of the analog circuit configurations satisfy predefined specifications under nominal operating conditions;
(c) select a base analog circuit configuration from among the analog circuit configurations that satisfy the predefined specifications;
(d) determine, through preliminary simulation, valid functional ranges for device sizes, device parameters, input conditions, output conditions, and Process-Voltage-Temperature (PVT) conditions within which the base analog circuit configuration remains functional and all constituent devices operate within prescribed operational limits;
(e) generate, using at least one random sampling method, a plurality of randomly generated combinations of device sizes, device parameters, input conditions, output conditions, and PVT conditions selected from within the determined valid functional ranges;
(f) perform SPICE simulations on the selected base analog circuit configuration for each of the plurality of randomly generated combinations to obtain simulation data comprising measured performance specification values;
(g) normalize and validate the simulation data using at least one data manipulation algorithm;
(h) construct a training dataset from the normalized and validated simulation data;
(i) train a machine-learning model using the constructed training dataset to generate a trained machine-learning model by
selecting a machine learning model suitable for the type of analog circuit configuration being designed;
optimizing hyperparameters of the machine learning model to minimize errors between predicted values and actual values; and
assessing performance of the trained machine learning model by determining a performance metric indicating predictive accuracy;
(j) execute, using inference from the trained machine-learning model on the one or more processors, at least one of design space exploration, design optimization, or fine-tuning of the analog circuit configuration without reverting to SPICE simulation; and
(k) generate a report for the analog circuit configuration based on results obtained from step (j).

17. The system of claim 16, wherein the system performs the design space exploration by:
(a) identifying dominant circuit components by computing sensitivity measures or correlation metrics;
(b) determining specification values using the trained machine learning model without SPICE simulation;
(c) modifying device parameters;
(d) iteratively repeating until convergence; and
(e) generating a design space exploration report with graphical visualizations.

18. The system of claim 16, wherein the system performs the design optimization by:
(a) receiving optimization criteria and boundary conditions;
(b) generating candidate analog circuit designs;
(c) determining boundary values using the trained machine learning model;
(d) identifying an optimized design by numerically solving multi-variable dependency relationships;
(e) validating boundary values; and
(f) iteratively recomputing until convergence.

19. The system of claim 16, wherein the system performs fine-tuning by:
(a) receiving an optimized analog circuit design comprising device-level parameters previously determined to satisfy nominal specification values across predefined PVT ranges;
(b) receiving, via a user interface, fine-tuning criteria comprising target PVT conditions, target specification values, and boundary conditions defining permitted ranges for one or more specification values;
(c) computing, by executing the trained machine learning model on the one or more processors, sensitivity measures or correlation metrics between variations in specification values and variations in each of a plurality of device parameters of the optimized analog circuit design using the multidimensional simulation data stored in the circuit-simulation data database;
(d) determining, from the sensitivity measures or correlation metrics and by numerically solving multi-variable dependency relationships encoded in the trained machine learning model, a set of device-parameter adjustments required to adjust one or more specification values of the optimized analog circuit design at the target PVT conditions;
(e) generating, by applying the determined device-parameter adjustments to the optimized analog circuit design, adjusted specification values at the target PVT conditions via execution of the machine-learning inference model;
(f) validating the adjusted specification values by comparing the adjusted specification values to the boundary conditions and determining whether the adjusted specification values satisfy the boundary conditions; and
(g) generating, when the adjusted specification values satisfy the boundary conditions, a fine-tuning report identifying the adjusted device parameters and the validated specification values.

20. A non-transitory computer-readable storage medium storing instructions that, when executed by one or more processors of a computing system comprising a machine-learning model and a circuit-simulation data database, cause the one or more processors to perform a method for designing analog circuits using machine learning models, the method comprising:
(a) generating one or more analog circuit configurations using at least one design tool;
(b) evaluating each of the one or more analog circuit configurations using at least one simulation tool to determine which analog circuit configurations meet predefined specifications under nominal conditions;
(c) selecting a base analog circuit configuration from among the analog circuit configurations that meet the predefined specifications;
(d) determining, through preliminary simulation, valid functional ranges for device sizes, device parameters, input conditions, output conditions, and Process, Voltage, and Temperature (PVT) conditions within which the base analog circuit configuration remains functional and all devices operate within operational limits;
(e) generating, using at least one random sampling method, a plurality of randomly generated combinations of device sizes, device parameters, input conditions, output conditions, and PVT conditions selected from within the determined valid functional ranges;
(f) performing SPICE simulations on the selected base analog circuit configuration for each of the plurality of randomly generated combinations to obtain simulation data comprising measured performance specification values;
(g) normalizing and validating the simulation data using at least one data manipulation algorithm;
(h) generating a training dataset from the normalized and validated simulation data;
(i) training a machine learning model using the generated training dataset to generate a trained machine learning model;
(j) performing at least one of design space exploration, design optimization, or fine-tuning of the analog circuit configuration using inference from the trained machine learning model executed on the one or more processors without reverting to SPICE simulation; and
(k) generating a report for the analog circuit configuration based on results from step (j).
